(19) United States
(12) Patent Application Publication
(10) Pub. No.: US 2009/0166867 A1
(43) Pub. Date: Jul. 2, 2009

(54) METAL INTERCONNECT STRUCTURES FOR SEMICONDUCTOR DEVICES

(76) Inventors: Harsono Simka, Saratoga, CA (US); Sadasivan Shankar, Cupertino, CA (US); Michael Haverty, Mountain View, CA (US); Ramanan Chebiam, Hillsboro, OR (US); Florian Gstrein, Portland, OR (US)

Correspondence Address: INTEL CORPORATION;c/o CPA Global, P.O. BOX 52050, MINNEAPOLIS, MN, 55402, US

(21) Appl. No.: 11/968,139

(22) Filed: Dec. 31, 2007

(51) Int. Cl. H01L 23/48; H01L 21/4763

(52) U.S. Cl. 257/751; 438/618; 257/E23.01; 257/E21.495

(57) ABSTRACT

Cu interconnect structures using a bottomless liner to reduce the copper interfacial electron scattering and lower the electrical resistance are described in this application. The interconnect structures comprise a nucleation layer and a liner layer that may be formed by an oxide or nitride. The bottom portion of the liner layer is removed to expose the nucleation layer. Since the liner is bottomless, the nucleation layer is exposed during Cu deposition and serves to catalyze copper nucleation and enable selective growth of copper near the bottom (where the nucleation layer is exposed), rather than near the liner sidewalls. Thus, copper may be selectively grown with a bottom-up fill behavior than can reduce or eliminate formation of voids. Other embodiments are described.

### FIELD

The invention relates to metal interconnection structures for semiconductor devices and metallization schemes for making the interconnections.

### BACKGROUND

Semiconductor devices are built using semiconductor, conducting, and dielectric (or insulating) materials, typically silicon wafers (or substrates), through a series of processes. These processes modify the silicon wafer by building components of the semiconductor devices in the wafer. The various components are electrically connected together using conductive layers, sometimes called interconnects or metal lines. Some of these processes form a metal interconnect layer which consists of separate metal lines. The combination of the metal lines and the various semiconducting and dielectric components together form the desired circuits and are, therefore, are sometimes referred to as integrated circuits.

As the demand for cheaper and faster semiconductor devices increases, so must the density of the semiconductor devices. Semiconductor manufacturers therefore continuously reduce or shrink the size of semiconductor devices so they can produce more components and devices for every wafer. This down-scaling process also makes formation of metal interconnect layers more challenging. As an example, the deposition of copper by a plating process (“gap-fill”) becomes more difficult due to the increasingly smaller openings at the top of the metal lines. The typical metallization scheme, which relies on a copper seed physical vapor deposition system (PVD), leads to undesired feature overhang, which reduces the available opening for copper plating.

### BRIEF DESCRIPTION OF THE DRAWINGS

The following description can be better understood in light of the Figures, in which:

FIG. 1 contains an illustration depicting an interconnect metallization scheme;

FIG. 2 contains a cross-sectional side view of some embodiments of a dual-damascene feature;

FIG. 3 contains an illustration depicting some embodiments of an interconnection metallization scheme;

FIGS. 4a and 4b contain illustrations depicting some embodiments of a method for making an interconnection metallization scheme;

FIG. 5 contains a table listing several components that may be used in electroless (EL) copper plating;

FIG. 6 contains a graph illustrating some hypothetical results; and

FIG. 7 contains a transmission electron microscope (TEM) view of some embodiments of selective copper deposition.

The Figures illustrate specific aspects of the semiconductor devices and associated methods of making and using such devices. Together with the following description, the Figures demonstrate and explain the principles of the semiconductor devices and associated methods. In the drawings, the thickness of layers and regions are exaggerated for clarity. It will also be understood that when a layer is referred to as being “on” another layer or substrate, it can be directly on the other layer or substrate, or with intervening layers present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such devices can be implemented and used without employing these specific details. For example, while the description focuses on semiconductor devices, it can be modified to be used in other electrical devices that are formed using similar methods in which higher density integration is needed. Although the description below focuses on metal interconnects between metal lines on a substrate, this process can be applied to other components of a semiconductor device.

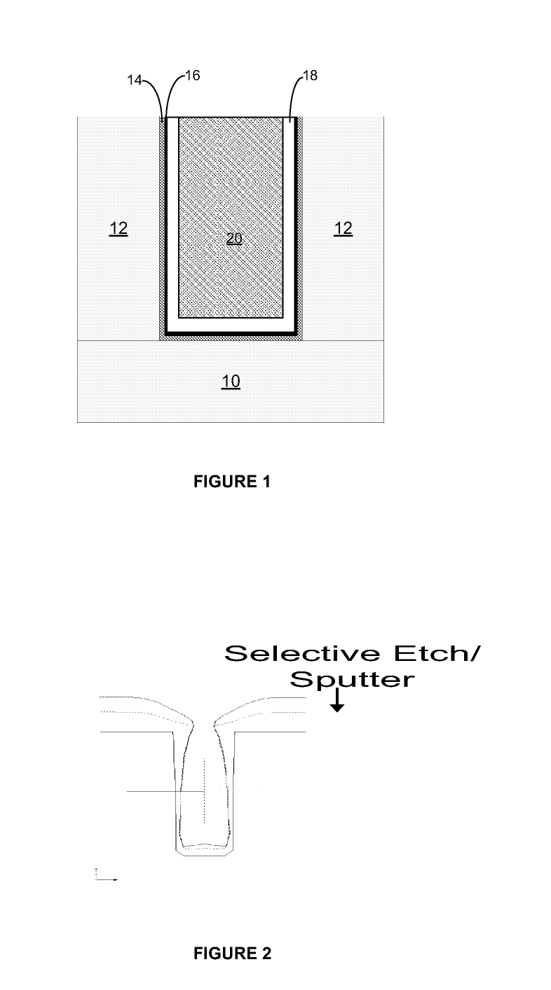

FIG. 1 illustrates a current copper metallization scheme for making metal interconnects. A dielectric layer 12, as illustrated in FIG. 1, is deposited onto a substrate 10. The dielectric layer 12 is etched to expose trenches. A barrier layer 14, typically formed of TaN, TiN, or WN is then provided on the bottom and sidewall of the trench. A liner layer 16, typically formed of Ta or Ru, is then provided on the bottom and sidewall of the barrier layer. A copper seed layer 18 is then deposited on the liner layer 16 using physical vapor deposition (PVD). The Cu seed layer 18 enables a subsequent copper deposition by electroplating (EP) on top of the seed layer, and filling of the recessed area of the trenches by a Cu layer 20.

As the trench size of these structures drops below 100 nm, copper resistivity increases strongly, which leads to higher effective via and line resistance. In addition, these structures have a reduced opening caused by overhang of copper that deposited by PVD, as shown in FIG. 2. In some cases, the EP copper may not scale properly once the trench opening becomes too narrow due to this overhang which can also lead to void defects in the deposited copper. While the liner layer can improve filling of these gaps, the current liner materials (Ta and Ru) may lead to significant electron scattering of conducting electrons at the interface between the copper and the liner. This interface electron scattering is one of the primary reasons for increase of copper resistivity in small features and lines.

Other methods for interconnect metallization contains a series of processes that enable lowering of such electron scattering and thereby reducing the line resistance in narrow features, including trenches with widths less than 45 nanometers. These methods use liner materials that reduce the copper thin film resistivity leading to lower line resistance. The liner may be removed to expose a nucleation layer or a catalyst layer from which the copper deposit may be grown.

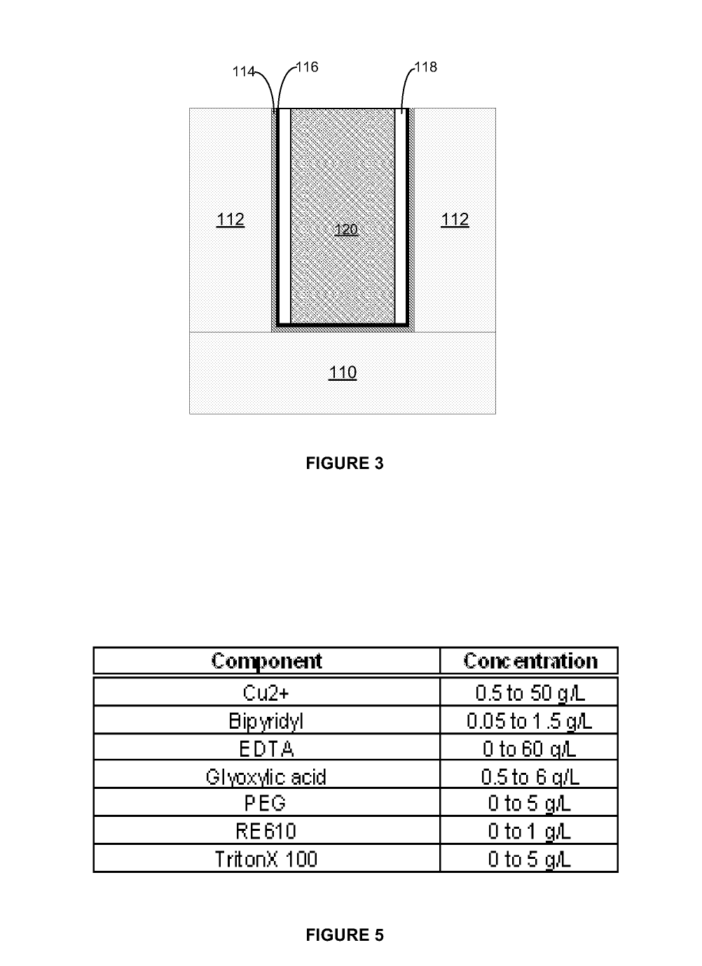

FIG. 3 illustrates an example of such interconnect structures. In the embodiments shown in FIG. 3, the interconnect structure may comprise of a copper film 120 deposited by electroless (EL) plating. The copper film 120 may be deposited on top of a resistive liner layer 118 that may cover the sidewalls but not the bottom of the trench. The interface between the EL plated copper and the liner 118 allow a reduction of copper interface electron scattering and, thereby, decrease copper resistivity. In some embodiments, a thin nucleation layer 116 may be used to catalyze copper nucleation, enabling selective deposition of copper through an EL plating, atomic layer deposition (ALD), and/or chemical vapor deposition (CVD), instead of through an EP processes.

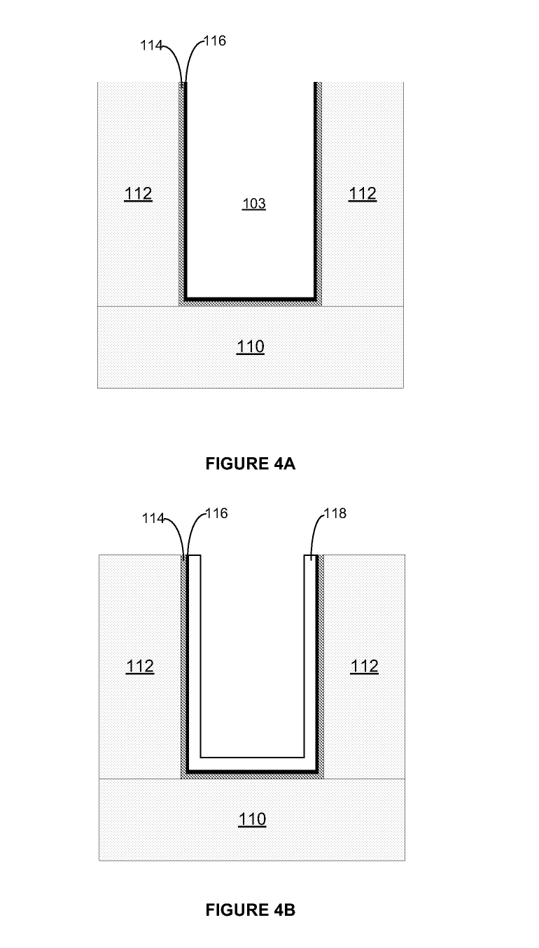

FIGS. 4a and 4b illustrate some embodiments of the methods for making such interconnection structures. A dielectric layer 102 is deposited onto a substrate 100 which can be a patterned metal layer or another dielectric layer, as shown in FIG. 4a. The dielectric layer 102 (also known as an interlevel dielectric layer or ILD) is then patterned and etched back so grooves, vias, trenches, or other recessed regions 103 expose a contact area to metal lines in the substrate 100. This etch can use any conventional etching process to remove the patterned dielectric material. The dielectric layer is then used to provide electrical and physical isolation to subsequently deposited conductive layers.

Next, a barrier layer 114 may be deposited within the trench 103. The barrier layer 114 may comprise a variety of materials, such as TaN. Moreover, the barrier layer may be deposited with the trench defined by the ILD in any suitable manner. For instance, the barrier layer may be deposited using any known PVD process.

FIG. 4a also shows that a thin nucleation layer 116 comprising a material suitable to catalyze copper nucleation may be deposited on the barrier layer 114. Some non-limiting examples of elements that may comprise the thin nucleation layer include ruthenium (Ru), copper (Cu), palladium (Pd), and/or other metals that may catalyze copper nucleation, such as silver (Ag), platinum (Pt), or nickel (Ni), as well as combinations of these materials. Even though the thin nucleation layer may be deposited on any portion of the barrier layer, in some embodiments, it may be beneficial to dispose the nucleation layer on the barrier layer towards the bottom of the trench 103.

The thin nucleation layer 116 may have any characteristic that allows the layer to catalyze copper nucleation. For example, the thin nucleation layer may be any suitable thickness between 0.5 to 5 nm. Also, the nucleation layer may be deposited in a variety of ways. Some non-limiting examples of ways in which the nucleation layer may be deposited may include atomic layer deposition (ALD) and/or chemical vapor deposition (CVD). Additionally, because conformality of the nucleation layer may not be critical as long as bottom coverage is achieved, PVD may also be used to deposit the nucleation layer.

Next, a resistive liner layer 118 may be deposited on the nucleation layer 116. In other embodiments, though, the nucleation layer 118 needs not be deposited on the barrier layer, but can be deposited directly on the barrier layer 114. The resistive liner may be deposited within the feature using various methods, including, but not limited to, PVD, ALD, CVD, and/or surface functionalization processes, which may include oxidation, silicidation, or nitridation with N₂ or NH₃ plasma.

The resistive liner 118 may comprise any suitable material that reduces resistivity in the interconnect lines or vias, including materials which may not allow direct copper plating. Some non-limiting examples of suitable liner materials may include oxides, such as beryllium oxide (BeO), tin oxide (SnO), calcium oxide (CaO), silicon dioxide (SiO₂), and/or aluminum oxide (Al₂O₃), and nitrides, such as nitrides of aluminum (AlNₓ), cobalt (CoNₓ), tungsten (WNₓ), and/or silicon (SiₓNₓ).

In order to enable copper metallization on top of the resistive liner 118, the bottom of the liner (or the region of the liner disposed towards the bottom of the trench), may be removed as shown in FIG. 3. Accordingly, the resistive liner layer 118 towards the bottom of the feature, which may often be too resistive, may be removed to expose either the nucleation layer or the barrier layer. Any known technique for removing the bottom region of the liner layer may be implemented to expose a portion of the nucleation layer or the barrier layer that is disposed towards the bottom of the feature. In some embodiments, the bottom region of the resistive liner may be removed using any suitable etching process. For instance, the bottom region of the liner may be etched away through exposure to argon ions (Ar⁺) in a sputtering or etching chamber. Thus, the nucleation layer or catalyst particles (e.g., palladium Pd, platinum Pt, gold Au, ruthenium Ru, copper Cu, etc.) may contact copper deposited at the bottom of the trench, but may not contact the copper deposited on the sidewalls of the feature.

Next, as shown in FIG. 3, copper is deposited within the space defined by the liner using a selective copper deposition. Any method of selective copper deposition known in the art may be used for this copper gap-fill process. For example, EL copper plating or a low temperature copper ALD/CVD process may be used for selective copper deposition. Both of these processes may have a substrate dependent nucleation rate, which may lead to preferential copper growth from the bottom end of the trench, thereby resulting in a bottom-up fill behavior. This bottom-up fill behavior may also act to prevent voids from forming due to pinch-off during the copper metallization process.

Where EL copper plating is used for the copper gap-fill process, any suitable components may be used to allow for selective deposition of copper and gap-fill with a bottom-up fill behavior. For example, FIG. 5 contains a list of some potential components that may be used in EL copper chemistry to enable the selective deposition of copper. The list also shows some exemplary concentration ranges of the components that may be used in electroless copper deposition. This list also includes some surfactants and additives that may be used to avoid conformal copper gap-fill.

The EL copper gap-fill process proceeds from the bottom of the trench and grows upwardly because of the nucleation layer. The Cu nucleates on the nucleation layer in a relatively short period of time (e.g. within minutes). Conversely, the EL copper does not nucleate well at all on the materials in the liner. Thus, EL copper preferentially grows faster at the bottom, where the nucleation layer is located, rather than on the sidewalls, where the liner is located.

The interconnect structure and metallization scheme illustrated in FIGS. 3, 4a, and 4b may be modified or varied in several ways. For example, as mentioned, the thin nucleation layer may not be deposited over the barrier layer. Instead, in such embodiments, the nucleation layer may be deposited directly on the barrier layer. In another example, the exposed surface of the barrier layer may be modified to enhance the charge-transfer reactions in the copper EL plating and/or ALD/CVD processes. For example, the exposed surface of the barrier layer may be modified using flash evaporation and incorporation of metal dopants, such as palladium Pd, platinum Pt, silver Ag, etc.

In other variations, the metallization scheme may also involve one or more surface pre-treatment strategies that may be used before copper is deposited within the liner 118. For example, before the copper deposition step, reduction in H₂ or forming gas (FG) may be used to improve the charge-transfer reactions of the exposed portion of the nucleation or the exposed portion of barrier layer disposed towards the bottom of the trench. In other variations, in place of a continuous nucleation layer, one or more metals or metal-oxide catalyst nanoparticles with a molecular linker may be embedded on the liner to catalyze the selective copper deposition.

In some embodiments, a layer of metal or metal oxide may be deposited on top of the liner before copper deposition. In these embodiments, a metal (such as palladium Pd, copper Cu, or ruthenium Ru) or a metal oxide (such as ruthenium dioxide RuO₂) may be deposited on top of the resistive liner 118 through an ALD or CVD process. Following the deposition of the layer of metal or metal oxide, it may be annealed in a reducing ambient that may reduce and activate the layer so it may act as a catalyst during the selective copper deposition step. For instance, through annealing in a reducing ambient, a layer of metal oxide may be reduced to a metal, which may serve as the catalyst in selective copper deposition. In yet other embodiments, surface oxides may be reduced by a chemical pretreatment, which may include reducing agents, such as H₂ or forming gas.

The interconnect structure and metallization scheme offer several benefits. For example, because a liner is deposited on the sidewalls while the bottom is covered by a catalytic or nucleation layer, the copper metallization can occur without gap-fill void defects in narrow features. Additionally, because copper can directly contact the barrier layer when the bottomless a liner is used, the interconnect structure may have reduced copper resisitivity. Also, EL copper plating and ALD/CVD processes preferentially nucleate on the exposed nucleation layer at the bottom of the trench. This nucleation from the bottom towards the top of the trench can reduce or prevent void defects caused by pinch-off.

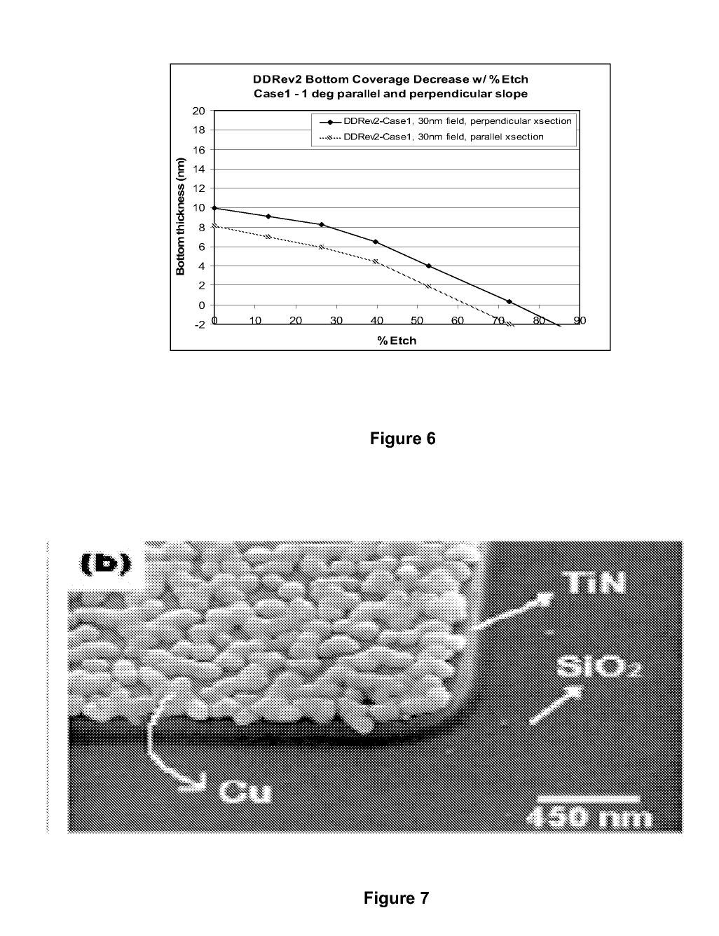

FIG. 6 contains the results of a theoretical simulation (which has been used for internal process development) illustrating the ability of selective removal of liner material from the bottom regions of the trench. In FIG. 6, a selective bottom etch of a copper seed layer is performed using Ar+ sputtering in a PVD chamber. The simulation in FIG. 6 illustrates that, in some embodiments, the selective bottom etch process may completely remove the bottom region of the liner. At the same time, the sidewall thickness may be increased.

FIG. 7 shows experimental results illustrating the selective nucleation of copper that has been deposited through a CVD process, as noted by Kwak et al., Current Applied Physics 2 (2002) p. 205-211. FIG. 7 illustrates that Cu which has been deposited through CVD may nucleate on a titanium nitride (TiN) material while the copper does not quickly grow on silicon dioxide. Accordingly, FIG. 7 illustrates the feasibility of a selective copper deposition on a nucleation layer.

Having described the preferred aspects of the semiconductor devices and associated methods, it is understood that the appended claims are not to be limited by particular details set forth in the above description, as many apparent variations thereof are possible without departing from the spirit or scope thereof.

1. A process for making an interconnect structure in a semiconductor device, comprising:
providing a dielectric layer on a substrate;
forming a trench in the dielectric layer;
depositing a barrier layer in the trench;
depositing a liner layer comprising an oxide or a nitride;
removing a bottom portion of the liner layer; and
depositing copper.

2. The process of claim 1, wherein the copper grows preferentially on the exposed barrier layer instead of the liner layer.

3. The process of claim 1, further comprising depositing a nucleation layer on the barrier layer so that it is located between the liner layer and the barrier layer.

4. The process of claim 3, wherein a portion of the nucleation layer is exposed when the bottom portion of the liner layer is removed.

5. The process of claim 3, wherein the nucleation layer comprises copper, ruthenium, palladium, platinum, silver, nickel, or combinations thereof.

6. The process of claim 1, wherein the resistive liner comprises beryllium oxide, tin oxide, calcium oxide, silicon dioxide, aluminum oxide, aluminum nitride, cobalt nitride, tungsten nitride, or silicon nitride.

7. The process of claim 3, wherein the copper grows preferentially on the exposed nucleation layer instead of the liner layer.

8. The process of claim 1, wherein the copper is deposited using electroless copper plating, atomic layer deposition, or chemical vapor deposition.

9. An interconnect structure for a semiconductor device made by the method comprising:
providing a dielectric layer on a substrate;
forming a trench in the dielectric layer;
depositing a barrier layer in the trench;
depositing a liner layer comprising an oxide or a nitride;
removing a bottom portion of the liner layer; and
depositing copper directly or after doing some surface modification.

10. The interconnect structure of claim 9, wherein the method further comprises depositing a nucleation layer on the barrier layer so that it is located between the liner layer and the barrier layer.

11. The interconnect structure of claim 10, wherein a portion of the nucleation layer is exposed when the bottom portion of the liner layer is removed.

12. The interconnect structure of claim 10, wherein the nucleation layer comprises copper, ruthenium, palladium, platinum, silver, nickel, or combinations thereof.

13. The interconnect structure of claim 9, wherein the resistive liner comprises beryllium oxide, tin oxide, calcium oxide, silicon dioxide, aluminum oxide, aluminum nitride, cobalt nitride, tungsten nitride, or silicon nitride.

14. The interconnect structure of claim 10, wherein the copper grows preferentially on the exposed nucleation layer instead of the liner layer.

15. The interconnect structure of claim 9, wherein the copper is deposited using electroless copper plating, atomic layer deposition, or chemical vapor deposition.
